(19) United States
(12) Patent Application Publication
(10) Pub. No.: US 2021/0190301 A1
(43) Pub. Date: Jun. 24, 2021

(54) COUPLING UNIT ATTACHED TO A COMPOSITE BOARD

(71) Applicant: LED iBond International A/S, Hørsholm (DK)

(72) Inventor: Lars FREDERIKSEN, Gentofte (DK)

(73) Assignee: LED iBond International A/S, Hørsholm (DK)

(21) Appl. No.: 17/051,872

(22) PCT Filed: May 2, 2019
(86) PCT No.: PCT/DK2019/050136

§ 371 Date: Oct. 30, 2020

(30) Foreign Application Priority Data
May 2, 2018 (DK) PA 2018 70260

(51) Int. Cl. F21V 21/04; H01R 33/94; F21V 19/00; F21K 9/20; H05K 1/18

(52) U.S. Cl. CPC F21V 21/04; H01R 33/94; H05K 1/184; F21K 9/20; F21V 19/001

(57) ABSTRACT

An electrical supply module including a composite board including a first and a second layer of an electrically conducting material separated by an insulator, which first layer forms an outer surface including a first electrical contact site, the composite board having a recess, allowing access to a second electrical contact site at the second layer, the recess having a coupling portion and a coupling unit having a complementary coupling portion allowing releasable coupling with the coupling portion of the recess, a first electrical contact area and a second electrical contact area, wherein coupling of the coupling portion and the complementary coupling portion establishes electrical connection from the first and second electrical contact sites to the first and second electrical contact areas, respectively. The electrical supply module provides a flexible device that allows freely adding and removing various electronic components to the composite board.

### FIELD OF THE INVENTION

The present invention relates to an electrical supply module, a coupling unit for attachment to an external unit and for releasable coupling with the electrical supply module and to an electrical supply system comprising the electrical supply module, the coupling unit and an external unit. The electrical supply module comprises a composite board with two layers of an electrically conducting material separated by an insulator and electrical contact sites for establishing electrical connection to electrical contact areas of the coupling unit. The electrical supply module allows easy, releasable coupling of the electrical supply module and the coupling unit, which in turn can be attached to the external unit having an electronic component, thus providing a greatly flexible system.

### PRIOR ART

Composite boards are well known construction elements with integrated electronic components, e.g. light emitting diodes (LED), where two electrically conducting plates separated by an insulating material are used to supply electricity to and from electronic components mounted in the composite board. For example, WO 2003/017435 discloses an adapter for electrical power transfer to an electronic component, e.g. a LED, for mounting in an aperture in such a composite board. The adapter comprises first pins establishing electrical connection with one of the layers when the adapter is mounted in an aperture, and a second pin adapted for establishing electrical connection with the other layer when mounting the adapter in the aperture.

WO 2017/121430 discloses an electrical supply module and an electrical supply system comprising the electrical supply module and an extension module. The modules comprise electronic components, and a constant voltage or a constant current between the anode layer and the cathode layer provide that a plurality of adapters with electronic components will be connected in parallel in the modules. Parallel connection of a plurality of electronic components with a constant current or a constant voltage in the electrical supply module provides a flexible system where additional electronic components can be added to or removed from the system in a simple fashion. A further similar system is described in WO 2018/077359.

US 2003/032337 discloses an adapter for a light emitter for mounting in an aperture in a sandwich board comprising a core of electrically insulating material provided with a layer of electrically conducting material at each side of the core. The adapter has a first pin for establishing electrical connection with one of the layers when mounting the adapter in the aperture, and a second pin for establishing electrical connection with the other layer when mounting the adapter in the aperture.

US 2016/190735 addresses the problem of converting AC voltage exiting typical electrical outlets to the DC voltage needed to power laptops, cellular telephones, smart phones, personal audio devices, and the like. US 2016/190735 discloses a device for use with an electrical buss comprising a carrier, a pair of electrically conductive elements linearly arranged along the carrier, and a linearly arranged ferromagnetic element carried by the carrier intermediate. The device comprises a housing adapted to be releasably couplable to the carrier in a plurality of orientations relative to the carrier, electrically conductive contacts carried by the housing, which are arranged such that an electrically conductive contact will engage a pair of electrically conductive contacts and a second electrically conductive contact will engage a different pair of electrically conductive contacts when the housing is releasably coupled to the carrier.

The Plane is a LED lighting fixture based on a composite board with LEDs generally integrated as described in WO 2003/017435 and the electric feed and the suspension are integrated into one magnetic connection.

However, the systems of the prior art do not allow easy and releasable coupling of the electrical supply modules, and there is a need for a more flexible system.

### DISCLOSURE OF THE INVENTION

The present invention relates to an electrical supply module comprising:
a composite board comprising a first layer and a second layer of an electrically conducting material, which first layer and second layer are separated by an insulator of an electrically insulating material, which first layer forms an outer surface comprising a first electrical contact site, the composite board having a recess extending through the outer surface, the first layer and the electrically insulating material, which recess allows access to a second electrical contact site at the second layer, the recess having a coupling portion, and
a coupling unit for attaching to an external unit using direct current, the coupling unit having a complementary coupling portion allowing releasable coupling with the coupling portion of the recess, a first electrical contact area and a second electrical contact area,
wherein coupling of the coupling portion and the complementary coupling portion establishes electrical connection from the first electrical contact site to the first electrical contact area and electrical connection from the second electrical contact site to the second electrical contact area, whereby the attachment of the external unit to the coupling unit allows for the correct current direction to the external unit.

In another aspect the invention relates to a coupling unit for coupling in a recess of an electrical supply module of the invention. The coupling unit comprises a complementary coupling portion complementary to the coupling portion of the recess of the electrical supply module, a first electrical contact area and a second electrical contact area,
wherein coupling of the complementary coupling portion and the coupling portion of the electrical supply module establishes electrical connection from the first electrical contact site of the electrical supply module to the first electrical contact area and electrical connection from the second electrical contact site of the electrical supply module to the second electrical contact area. Any embodiment of the coupling unit is relevant for any embodiment of the electrical supply system, and vice versa.

In a further aspect the invention relates to an electrical supply system comprising the electrical supply module, the coupling unit and an external unit. The electrical supply system may comprise any embodiment of the electrical supply module and any embodiment of the coupling unit.

The electrical supply module provides a flexible device that allows freely adding and removing various electronic components, e.g. as part of the external unit, to the composite board, which provides power to the electronic components. The coupling unit is designed to fit the recess of the composite board, whereas the attachment to the external unit is only limited by the design of the coupling unit in so far as electrical contacts can be established between the electrical contact areas of the coupling unit with appropriate electrical contact points of the external unit. The sizes of the electrical contact areas of the coupling unit provide flexibility in the attachment to the external unit with respect to positioning of the electrical contact points of the external unit. For example, the first electrical contact area of the coupling unit may follow the circumference of the coupling unit so that the corresponding electrical contact point may be placed anywhere on the external unit which will be in contact with the circumference of the coupling unit. By having the coupling unit that is releasably coupled in the recess of the composite board, the coupling unit may advantageously be exchanged e.g. if another type of external unit is to be attached to the coupling unit. This enables to have a constant recess size for the electrical supply module and only vary the size of the coupling unit. This further allows the attachment of a variety of different external units to the composite board without being dependent on their size. The coupling unit also enables a faster and easier exchange of the external unit without substantially having to disassemble anything on the composite board. The electrical supply module may be installed such that it is difficult and cumbersome to access, and this easy access to the external unit facilitates the process of exchanging the coupling unit and external unit. Also when a large number of external units are to be replaced or exchanged, the process is further facilitated by having a consistent way of exchanging the external units independently of their size.

Thus, the coupling unit allows greater flexibility for connecting an external unit having an electronic component to a power supply than a composite board not including a coupling unit. The external unit uses a direct current, e.g. the external unit may comprise an electronic component using direct current. Attachment of the external unit to the coupling unit allows for the correct current direction to the external unit. In a particular embodiment, attachment of the external unit to the coupling unit only allows for the correct current direction to the external unit so that incorrect electrical connections are prevented, e.g. an electrical connection cannot be established from the first electrical contact area to the second electrical contact site, and an electrical connection cannot be established from the second electrical contact area to the first electrical contact site. Thus, another advantage of having a coupling unit e.g. as an adapter between the composite board and the external unit, is that the risk of errors e.g. as switching the poles around such that the current direction would be wrong, when connecting and disconnecting the external unit using direct current, may be avoided. The way of attaching the external unit through the coupling unit provides automatic electrical connections of the poles, which minimises the risk of errors and short circuits.

In the context of the invention an “electrical supply module” is a module for supplying electricity to an external unit attached to a coupling unit. The external unit has an electronic component, and any electrical or electronic component is contemplated for the invention. An electronic component may be carried on a circuit board in the external unit, or the external unit may be considered to be an electronic component. The electrical supply module may also comprise additional electronic components, e.g. mounted in recesses or on the outer surface and in appropriate electrical connection to both the electrically conducting front and back layers. The electrical supply module has a first layer, or “front layer”, that can be in electrical connection with a first electrical contact area of the coupling unit, and a second layer, or “back layer”, that can be in electrical connection with a second electrical contact area of the coupling unit. The first layer may also be referred to as the “anode layer”, and second layer may also be referred to as the “cathode layer”. Likewise, the first electrical contact area of the coupling unit may also be referred to as the “anode contact area” of the coupling unit, and the second electrical contact area of the coupling unit may also be referred to as the “cathode contact area” of the coupling unit. Correspondingly, the first layer and the first electrical contact areas may be cathodic and the second layer and the second electrical contact areas may be anodic. The anode layer of the composite board can be electrically connected to an anode of the electronic component, and the cathode layer of the composite board can be electrically connected to a cathode of an electronic component, but the anode layer and the cathode layer are otherwise not limited. Either of the front layer or a back layer of the composite board may represent the anode layer or the cathode layer, and correspondingly, either of the first electrical contact area and the second electrical contact area of the coupling unit may represent the anode contact area or the cathode contact area. In the context of the invention the anode layer and the cathode layer may be referred to collectively as the “electrically conducting layers” or “conducting layers”. The conducting layers may be used for carrying the electrical power in either direction including the opposite direction.

The electrical supply module has a coupling unit that can be mounted in the recess and coupled with the composite board, and the recess of the composite board has a coupling portion complementary to a coupling portion of the coupling unit, i.e. a complementary coupling portion. The coupling portions may have any shape as desired and be made of any appropriate material.

The coupling portion of the recess may have any form allowing it to be releasably coupled to the complementary coupling portion of the coupling unit. The coupling portions are generally referred to as “complementary”, and the coupling portion of the coupling unit will be referred to as the “complementary coupling portion”. It is to be understood that the coupling portion of the electrical supply module is complementary to the coupling portion of the coupling unit even though the term “complementary” is not used. The releasable coupling between the coupling portion of the recess and the complementary coupling portion of the coupling unit may employ any appropriate principle as desired, and in general it is to be understood that “releasable” means that the coupling portion of the recess of the electrical supply module can be coupled with and separated from the complementary coupling portion of the coupling unit without influencing future coupling between the coupling portion and the complementary coupling portion. Exemplary coupling principles comprise male-female interactions, magnetic forces, press-fit interactions, click-lock interactions, complementary external and internal helical threads, spring-lock interactions, or any combination of these. In a certain embodiment, the recess has a coupling portion that is integrated into the surface of the composite board. For example, the composite board may have a circular recess with an internal helical thread, and the coupling unit may also be circular and have a complementary external helical thread. The coupling portion, e.g. a metallic coupling portion, may follow the perimeter of the recess and the coupling unit may be mounted in the recess with a press-fit or another principle of interaction. A metallic coupling portion along the perimeter of the recess may also be referred to as a “locking ring”, also if the recess is not circular. In another embodiment, the recess may have an internal helical thread as the coupling portion, or the recess may have a magnet as the coupling portion.

The coupling unit is suitably mounted in the recess of the composite board, when the coupling portion and the complementary coupling portion are coupled together. However, the coupling unit may also be positioned on the outer surface with a conductor, e.g. as part of the coupling unit, extending into the recess. In the context of the invention, this is also considered to represent “mounting in the recess”. The coupling unit may be fully contained in the recess so that it is flush with the surface of the electrically conducting front layer when the coupling portion and the complementary coupling portion are coupled together.

In the context of the invention a “coupling unit” is a unit having a first electrical contact area and a second electrical contact area, which can be electrically connected to the first electrical contact site and the second electrical contact site of the electrical supply module, respectively, when the coupling unit is coupled with the coupling portion of the coupling unit of the electrical supply module. Coupling of the coupling portion with the complementary coupling portion establishes electrical connection from the first electrical contact site of the composite board to the first electrical contact area of the coupling unit and electrical connection from the second electrical contact site of the composite board to the second electrical contact area of the coupling unit. The second electrical contact site is located in the recess in the composite board and electrical contact to the first electrical contact area of the coupling unit may be established as desired. For example, the coupling unit may comprise a conductor for establishing the electrical contact. Alternatively, the recess may comprise a conductor for establishing the electrical contact. A conductor may also be an entity separate from the coupling portion and the coupling unit.

The coupling unit may be attached to an external unit comprising any electrical or electronic component, which is electrically connected to the first electrical contact area and the second electrical contact area so that when the first electrical contact area and the second electrical contact area are connected to a power supply an electrical circuit with the electrical or electronic component is obtained.

The electrical supply module may further comprise a power supply. The power supply may provide a direct current or an alternating current. The power supply, e.g. a power supply providing a direct current, may be connected to the electrical supply module as desired. For example, the power supply may be wired to the anode layer and the cathode layer at any location on the composite board. In certain embodiments the power supply provides a constant voltage of a standardised value, e.g. 12 V or 24 V. It is likewise preferred that the electrical or electronic component is a low voltage application, e.g. an application requiring a voltage in the range of 1 V to 60 V, e.g. 12 V or 24 V. In another embodiment the power supply provides a constant current.

In another embodiment the electrical supply module is defined in terms of a “nominal voltage”, e.g. the electrical supply module has a nominal voltage, for example, the electrical supply module has an electronic component with a nominal voltage, and the power supply is capable of providing between the first layer and the second layer, a first constant voltage equal to or higher than the nominal voltage of the external unit and a second constant voltage lower than the nominal voltage of the external unit. In a specific embodiment, the external unit has the nominal voltage. In another embodiment, the composite board has the nominal voltage. In a further embodiment, both the external unit and the composite board have a nominal voltage, which may be the same or different, e.g. the nominal voltage of the composite board may be higher than, e.g. a “maximal” nominal voltage, the nominal voltage of the external unit, e.g. an “intermediate” nominal voltage, or vice versa. When the external unit and the composite board have different nominal voltages, e.g. an intermediate nominal voltage and a maximal nominal voltage, the power supply may be capable of providing an intermediate constant voltage equal to or higher than the intermediate nominal voltage, a maximal constant voltage equal to or higher than the maximal nominal voltage, and a constant voltage below the intermediate nominal voltage. It is to be understood that when the composite board comprises an electronic component, the electronic component will be electrically connected to the first and the second layers of the composite board, as appropriate.

The nominal voltage may for example be the voltage required to power an electronic component. Thus, the composite board may comprise an electronic component having the nominal voltage, or the external unit may comprise an electronic component having the nominal voltage. When the composite board comprises an electronic component having the nominal voltage, the external unit may comprise an electronic component requiring a lower voltage than the nominal voltage. When the external unit comprises an electronic component having the nominal voltage, the composite board may comprise an electronic component requiring a lower voltage than the nominal voltage.

Any electronic component requiring a nominal voltage to operate is contemplated in the invention. A preferred electronic component having a nominal voltage is a light emitting diode (LED). For a LED the nominal voltage may also be referred to as the forward voltage (V_{f}), and the two terms may be used interchangeably.

When the electrical supply module has a nominal voltage and a power supply with the two or three constant voltages defined above, it is possible to have a low voltage where electronic components having the nominal voltage can be switched off while the constant voltage is still sufficient to power electronic components having the lower nominal voltage. Thus, the power supply module can power “background electronic components” while switching off other electronic components. When the external unit has the nominal voltage, an electronic component having the nominal voltage of the external unit can be switched off and may thereby be exchanged or replaced without turning the power supply to electronic components of the composite board off so that background electronic components are still powered. This combined with the fact that the coupling unit is used to attach the external unit, simplifies even further the exchange of external units. It may further allow powering only some external units while others are off.

In a specific embodiment, the electrical supply module is or is part of a control system for a controllable external system. In this embodiment, the composite board comprises electronic components, e.g. electronic components for controlling the external system, requiring a constant voltage below the nominal voltage, and the electrical supply module has a power supply capable of providing constant voltages at or above the nominal voltage, e.g. the forward voltage of an LED, and below the nominal voltage. The electrical supply module comprises one or more external units with LEDs. The composite board may comprise a user interface for receiving input from a user and providing information to the user. The composite board may also comprise a sensor capable of detecting the presence of a user. When no user is present, the power supply will provide a constant voltage below the forward voltage. When a user is detected by the sensor, or when a user provides input to the control system of his presence, the power supply may switch to a voltage at or above the forward voltage to turn on the LEDs. The user may further provide input to control the external system. This embodiment of the electrical supply module is particularly useful in an elevator or the like.

An electronic component is preferably carried on a circuit board, which comprises electrical conductors appropriately connecting the electronic component to the first electrical contact area and the second electrical contact area so that an electrical circuit is formed between the electronic component and a power supply connected to the first and the second electrically conducting layers. A “circuit board” may be any component capable of carrying an electronic component and establishing electrical connection to the first electrical contact area and the second electrical contact area of the coupling unit. However, a circuit board is not needed for establishing electrical connection, and electrical connection may be established as desired. The circuit board is not limited to a “board” shape and is defined solely by its function. In its simplest form the circuit of the circuit board provides electrical contacts between the anode and the cathode of the electronic component and the electrical contact areas of the coupling unit. The circuit board may be any kind of material, e.g. plastic, metal etc., provided with the circuit for transmission of electricity. The circuit may be attached to the circuit board in any way, e.g. by printing, soldering, gluing or the like. In a certain embodiment the circuit board is a printed circuit board (PCB).

The external unit is not limited to a single electronic component, and in an embodiment the external unit comprises several electronic components, e.g. several electronic components forming a low voltage application. When several electronic components are contained in a single coupling unit, these are preferably on a single circuit board. Exemplary electronic components are a LED, a series of LEDs, a resistor, a transistor, a controller, a chip on board (COB), a driver, a speaker, a USB hub, a power bank, a microphone, a camera, a sensor, a 3D sensor, a positioning device, a transmitter, a radio transmitter, a receiver, a radio receiver, an antenna, an access point for wireless communication, and a projector. The external unit may for example be a speaker, a USB hub, a power bank, e.g. a power bank with one or more rechargeable batteries, such as for charging a smart phone or another portable electronic device, a radio transmitter/receiver, such as a Bluetooth, WiFi or an Airplay device, a sensor, such as a sensor for temperature, humidity, wind, light, sound, movement, etc., a camera, a microphone, or a lamp, such as an LED lamp. Electronic components are preferably in a surface mounted form. When several electronic components are employed these may be connected as desired, e.g. in series or in parallel.

The external unit may also be in data communication via the electrically conducting layers, e.g. using power line communication (PLC), such as direct current PLC. In a specific embodiment, the composite board comprises additional electrically conducting layers for transfer of data. Additional electrically conducting layers may be in electrical communication via conductors, e.g. additional conductors in the coupling portion of the composite board, and the coupling portion may thus comprise further electrical contact sites located to establish electrical connection with further electrical contact areas of the external unit. When the electrical supply module employs PLC, especially direct current PLC, the current carrying the communication may have the opposite polarity of the current providing power to the external units. In a specific embodiment, the electrical supply module comprises two or more, e.g. a plurality, of recesses, and two or more coupling units, and the electrical supply module further comprises a controller for transmitting data via the first and/or the second conducting layers, e.g. via direct current PLC. The controller may be integrated in the composite board, e.g. be in electrical communication with the first and the second conducting layers, or the controller may be included in an external unit, in particular an external unit attached, e.g. permanently attached, to a coupling unit. This embodiment allows an end user flexibility in designing a system comprising a number of electronic components where data is to be transmitted between the electronic components, or where electronic components are to be controlled individually.

The recess of the composite board may have any size and shape, e.g. with respect to the outer surface, and it may have a conductor to allow electrical connection to the electrically conducting back layer. For example, the recess may be circular, square, rectangular, or polygonal, or it may be shaped freely. The recess preferably has a circular perimeter. In general, the cross-sectional dimensions of the recess, i.e. with respect to the outer surface, will typically be in the range of 1 mm to 100 mm. The recess may have a first dimension in the range of 5 mm to 50 mm, and a second dimension in the range of 5 mm to 50 mm. For example, the recess may be circular and have a diameter in the range of 5 mm to 50 mm. The recess may also be larger, e.g. having a diameter up to or at 100 mm. Regardless of its shape, the recess will have a centre and it may be defined by one or more alignment points. The alignment points may be at any location in the outer surface. The coupling unit will also have a “centre” corresponding to the centre of the recess, and “alignment points” corresponding to the alignment points of the recess. When the coupling unit is coupled with the coupling portion of the recess of the electrical supply module with the alignment points and the centres being in alignment, electrical connections between the first electrical contact site and the first electrical contact area of the coupling unit, and between the second electrical contact site and the second electrical contact area of the coupling unit are established. The coupling unit may also be coupled with the coupling portion at an inactive, i.e. “non-aligned”, coupling where no electrical connections are established, but in the following the terms “alignment” and “aligned coupling” refer to coupling with the centres and the alignment points being in alignment so that the correct electrical connections are established.

In an embodiment, the coupling unit and/or the recess comprise(s) a conductor. The conductor may be of any electrically conducting material, and it may have any size and shape. Exemplary materials are metals, e.g. aluminium, copper, silver, gold, brass, stainless steel, iron or a combination thereof. For example, the conductor may be of any metal with a coating of gold. The conductor may comprise any number of sub-elements, e.g. electrically conducting sub-elements, in mutual electrical connection. The conductor may be a pin or rod with a cross-sectional dimension, e.g. a diameter, in the range of 0.1 mm to 5 mm. The length of the conductor is not limited, and it may be shorter or longer than the overall thickness of the composite board.

The first electrical contact site may be in the same plane as the outer surface, it may be in the recess, e.g. “below” the outer surface, or it may extend from the recess to be outside the plane of the outer surface. In general, the second electrical contact site may be at any location on the conductor. In a specific embodiment, the second electrical contact site, e.g. represented by the end of the conductor, is located on or in the outer surface of the composite board. For example, when the recess has a conductor, the first and the second electrical contact sites may be in the same plane, e.g. in plane with the outer surface of the composite board.

In a specific embodiment, the recess has a conductor, which is separated from the first layer by an electrically insulating material to prevent short circuits. For example, the recess may have a conductor with an electrically insulating material, which conductor is arranged so that the first and the second electrical contact sites are in plane with the outer surface of the composite board. In another embodiment, the coupling unit has a conductor having an electrically insulating material, which is arranged to prevent contact between the conductor and the first layer to prevent short circuits.

It is also contemplated that the conductor is simply an access area in the second layer of the electrically conducting material, and that the coupling unit comprises an appropriate conductor, e.g. a wire, rod, pin or the like comprising or being made of a metal, to allow electrical connection to the second electrical contact site.

The conductor may be permanently mounted in the recess, or it may also be releasably positioned in the recess. Regardless of the integration of the conductor with the composite board, the recess or the coupling unit, it is preferred that the conductor comprises electrical insulation adapted to prevent contact between the conductor and the electrically conducting front layer. Thereby, short circuits are prevented. Moreover, the electrical insulation further provides a more compact system. For example, an electrically insulated conductor allows that a single coupling portion can house both the first electrical contact site and the second electrical contact site, and moreover that the complementary coupling portion of the coupling unit can house both the first electrical contact area and the second electrical contact area of the coupling unit. An electrical insulator may form part of the coupling portion of the electrical supply module, or the coupling unit, or both.

In an embodiment, the conductor, which is preferably part of the coupling unit or the recess, comprises a spring, e.g. as part of the conductor, which is made of an electrically conducting material. A conductor comprising a spring is preferably in the form of a pogo-pin. Alternatively, the conductor is a spring. The spring may have any shape as desired but is preferably a helical spring. A spring provides flexibility for coupling the coupling unit with the composite board. For example, a conductor having or being a spring allows tight electrical connection between the back layer and the second electrical contact area of the coupling unit, and moreover, the flexibility allows that the coupling unit is coupled to the composite board without visible gaps.

The first electrical contact site may be located at any position in the outer surface, and its position may be independent of the location of the recess. For example, the first electrically conducting layer may be metallic without any electrical insulation so that any point in the outer surface can be chosen as the first electrical contact site.

The first electrical contact site and the second electrical contact site may be located at any distance from each other as desired. In an embodiment, the first electrical contact site and the second electrical contact site are located, e.g. on or in the outer surface of the composite board, at a distance in the range of 1 mm to 100 mm. In another embodiment, the first electrical contact site and the second electrical contact site are adjacent to each other at a minimal distance, e.g. separated by an electrically insulating material, which prevents short circuits between them.

In an embodiment, the outer surface comprises an electrically insulating layer and a hole through the electrically insulating layer of the outer surface allows electrical contact to the first electrical contact site. For example, the outer surface may be covered, e.g. fully covered, with the electrically insulating layer. An electrically insulating layer can appropriately be a metal oxide layer of an anodised metal, e.g. aluminium, magnesium or titanium. A hole in the electrically insulating layer may have any size, shape and location in the outer surface.

In a certain embodiment, the electrically insulating layer is a metal oxide layer of an anodised metal, and the hole in the electrically insulating layer comprises a connector element allowing electrical connection to the first electrically conducting layer. However, the connector element may be employed with any embodiment of the first electrically conducting layer. For example, when the first electrically conducting layer is a metal without an electrically insulating layer, or when an electrically insulating layer is present but is different from a metal oxide layer, a connector element may be used.

The connector element may comprise, e.g. be made of, an electrically conducting material, e.g. a metal which is not prone to oxidation, such as stainless steel, gold, copper, brass, silver, or nickel, or a combination thereof. The metal of the connector element may be the same or different from the material of the first electrically conducting layer. The connector element may have any shape and form as desired. For example, the first electrically conducting layer may be coated, i.e. at the first electrical contact site, with a metal which is not prone to oxidation, so that this metal allows electrical connection to the first electrical contact site, regardless of the presence of an electrically insulating layer.

Regardless of the shape of the connector element it is preferred that its deviation is marginal compared to the plane of the outer surface. For example, the connector element may be flush with the outer surface, or it may extend up to 1 mm away from the plane of the outer surface. It is also possible that the connector element is located in a depression in the plane of the outer surface, e.g. a depression of up to 1 mm from the plane of the outer surface.

In a certain embodiment, the composite board has a single recess for establishing electrical connections with the anode and the cathode to the anodic and the cathodic layers, respectively. For example, electrical connection to the back layer, i.e. the second electrical contact site, may be established via a conductor in the recess, e.g. the recess or the coupling unit may have a conductor, and electrical connection to the front layer, i.e. the first electrical contact site, may be established at the perimeter of the recess. In another embodiment, the composite board has a recess for establishing electrical connection to the back layer via the conductor, where electrical connection to the front layer at, or in the vicinity of, the perimeter of the recess is not possible. For example, the perimeter of the recess may comprise an electrical insulator preventing electrical connection with the front layer at the perimeter of the recess. Electrical connection to the front layer, i.e. the first electrical contact site, is then established at a distance, e.g. with 1 mm to 100 mm, from the recess of the composite board.

The coupling unit is suited for attachment to an external unit. In the context of the invention any means of attaching the external unit and the coupling unit are appropriate. The attachment may be permanent, so that separation of the coupling unit and the external unit will result in the destruction of either or both of the coupling unit and the external unit. The attachment may also be releasable so that the external unit can be released from the coupling unit to be reattached subsequently without detrimental effects on the attachment, the coupling unit or the external unit. Any coupling principle discussed for the coupling portion and the complementary coupling portion is also appropriate for the attachment of the external unit and the coupling unit. Other relevant principles comprise gluing, welding, laser welding, ultrasonic welding, physical attachment etc.

In general, the external unit may be electrically connected to the coupling unit as desired, as long as the attachment establishes an electrical circuit between the electronic component and the electrically conducting layers when the coupling unit with the attached external unit is coupled in the recess. For example, the external unit may have a first and a second electrical contact point that are electrically connected to the first electrical contact area and the second electrical contact area of the coupling unit, and which electrical contact points are electrically connected to terminals of the electronic component.

The external unit is attached to the coupling unit as described above, and the coupling unit may be mounted in the recess of the composite board. Thereby, the coupling unit and the external unit may be fully contained in the recess to be flush with the surface of the electrically conducting front layer, when the coupling unit is coupled with the composite board. Alternatively, the external unit may extend from the outer surface of the composite board. Any combination between these extremes is also possible.

In an embodiment, both the first electrical contact site and the second electrical contact site are located on the perimeter of the recess, and the first electrical contact site, e.g. in the form of the connector element defined above, and the second electrical contact site are separated from each other using any appropriate electrically insulating material, and likewise the first electrical contact site is electrically isolated from the back layer, and the second electrical contact site is electrically isolated from the front layer. For example, the perimeter may have one or more sections representing the first electrical contact site, one or more sections representing the second electrical contact site with electrically non-conducting sections in the perimeter between each section representing the first and the second electrical contact sites, respectively. The first electrical contact site, the second electrical contact site, and the electrically non-conducting sections may each take up any percentage of the length of the perimeter, e.g. the circumference of a circular recess, with the total length of the three sections corresponding to the total length of the perimeter. Thereby, a continuous structure of material is present at the perimeter of the recess, which provides a more robust coupling between the coupling portion of the recess and the complementary coupling portion of the coupling unit. Furthermore, when both the first electrical contact site and the second electrical contact site are located on the perimeter of the recess coupling of a single set of a coupling portion, i.e. of the electrical supply module, and a complementary coupling portion, i.e. of the coupling unit, provides the establishment of the aligned electric connections in a single action. For example, the coupling unit may be “plugged in” to the electrical supply module.

In a specific embodiment, the first electrical contact site and the second electrical contact site are located on the perimeter of the recess and separated from each other, e.g. by an electrically non-conducting block or air, at a distance along the perimeter at least equal to the largest extension along the perimeter of the two electrical contact sites. For example, the recess may be circular, and the first electrical contact site and the second electrical contact site may each take up up to 25% of the perimeter and be located opposite each other. The first electrical contact site and the second electrical contact site thus provide alignment points of the recess. When the coupling unit has electrical contact areas, i.e. the first electrical contact area and the second electrical contact area, at corresponding alignment points of the recess, a system is provided where it is impossible to incorrectly connect the coupling unit so that the only possible electrical connections are aligned, creating electrical connections from the first electrical contact site to the first electrical contact area of the external unit and from the second electrical contact site to the second electrical contact area of the coupling unit. In a certain embodiment, the coupling portion of the recess of the electrical supply module is coupled to the complementary coupling portion of the coupling unit via a press-fit interaction or a click-lock interaction. In another embodiment, the recess is circular, and the coupling unit can be rotated in the recess to establish the aligned electrical connections, while preventing incorrect electrical connections. In a specific embodiment, the recess is circular, and the coupling unit can be rotated in the recess to a locked, and aligned, configuration, e.g. via a click-lock interaction, where the aligned electrical connections are established. The recess, e.g. a circular recess, may also comprise an internal helical thread complementary to an external helical thread of the coupling unit.

In a further embodiment, the first electrical contact site is located at or along the perimeter of the recess, which is preferably circular, and the second electrical contact site, e.g. the conductor, is located at a central section of the recess. The first electrical contact site may take up any percentage of the perimeter of the recess, e.g. from 10% to 100% of the perimeter. Any point in the first electrical contact site may represent an alignment point, but preferably an alignment point is defined in the centre of the first electrical contact site. The second electrical contact site may take up any percentage of the cross-section, i.e. defined in relation to the outer surface of the composite board, of the recess, but regardless of the percentage the second electrical contact site represents the centre of the recess. When the coupling unit has electrical contact areas, i.e. the first and the second electrical contact area at corresponding alignment points, a system is provided where it is impossible to incorrectly connect the coupling unit so that the only possible electrical connections are in alignment. The coupling portion of the recess of the electrical supply module may be coupled to the complementary coupling portion of the coupling unit via a press-fit interaction, a click-lock interaction, or with magnetic forces. In an embodiment, the recess is circular, and the coupling unit can be rotated in the recess to establish the correct electrical connections, while preventing incorrect electrical connections. In a specific embodiment, the recess is circular, and the coupling unit can be rotated in the recess to a locked configuration, e.g. via a click-lock interaction or magnetic forces, where the correct electrical connections are established. The recess, e.g. a circular recess, may also comprise an internal helical thread complementary to an external helical thread of the coupling unit. Likewise, it is also possible for the conductor, e.g. in the form of a rod, to comprise an external helical thread complementary to an internal helical thread of the second electrical contact area of the coupling unit.

In a certain embodiment, the recess or the coupling unit has a conductor, which has the form of a pogo pin. A pogo pin is relevant both when the conductor is part of the recess and the coupling unit. Pogo pins are well-known to the skilled person, but in general a pogo pin comprises an outer barrel with a barrel wall and a closed end section opposite an open section having a collar. A piston section having a first cross-sectional dimension, e.g. a diameter, smaller than a cross-section, e.g. a diameter, of the outer barrel but larger than a cross-sectional dimension, e.g. a diameter, of the collar is inserted into the outer barrel, and the outer barrel contains a spring adapted to push the piston section away from the closed end, so that the piston section is retained in the outer barrel. Without an external load the spring extends the pogo pin to its maximal extension, since the collar retains the piston section in the outer barrel, and when a load is applied to push the piston section towards the closed end, the spring will ensure tight connection between the piston section and the load. The minimal extension of the pogo pin typically corresponds to the length of the outer barrel. Both the outer barrel and the piston section are metallic or comprise metallic sections so that the piston section and the outer barrel are in electrical connection regardless of the extension of the pogo pin. Thereby, a pogo pin allows tight but flexible electrical connections between the second electrical contact site of the composite board and the second electrical contact area of the coupling unit.

It is furthermore possible in any embodiment that the coupling portion and/or the complementary coupling portion comprise magnets. When magnets are employed their positions generally represent alignment points. For example, the coupling portion of the recess of the electrical supply module may comprise a magnet and the coupling unit may comprise a ferromagnetic material, or vice versa. In another embodiment, both the coupling portion of the recess and the coupling portion of the coupling unit each comprise a magnet. Preferred magnets are permanent magnets, e.g. a neodymium magnet or a neodymium/iron/boron (NdFeB) magnet.

Magnets may be located at any position in the composite board, and it is preferred that the external unit also has a magnet or a ferromagnetic material at the corresponding alignment points so that coupling of the coupling unit with the recess will establish correct, aligned electrical connections while at the same time holding the coupling unit in place on the composite board. In a preferred embodiment, the recess is circular and the composite board has a magnet located at an alignment point a distance in the range of 1 mm to 100 mm from the centre of the recess with a pole, e.g. the north pole or the south pole, facing the outer surface, and the coupling unit has a ferromagnetic material or a magnet with its pole opposite the pole of the magnet of the composite board at the corresponding alignment point. Thereby, the coupling unit can be held in place to establish the aligned electrical connections. It is especially preferred that the composite board has a first magnet located at a first alignment point at a distance in the range of 1 mm to 100 mm from the centre of the recess with its north pole or its south pole facing the outer surface, and an additional magnet at a second alignment point at a distance in the range of 1 mm to 100 mm from the centre of the recess with its pole opposite the pole of the first magnet facing the outer surface. For example, the south pole of the first magnet may face the outer surface and the north pole of the additional magnet may face the outer surface, or vice versa. When the coupling unit has oppositely facing magnets in the corresponding alignment points it will not be possible to incorrectly couple the coupling unit with the coupling portion of the recess of the composite board, so that the coupling only can be aligned.

Magnets in the composite board, with aligned magnets or ferromagnetic materials in the coupling unit may be combined with any other coupling principle. In an embodiment, the magnets in the composite board are electromagnets. For example, the composite board may comprise, i.e. at alignment points, ferromagnetic pins, e.g. positioned normal to the outer surface, between the first and the second layer of the electrically conducting material, with a conducting wire, e.g. a copper wire, wound around the ferromagnetic pins, and with the conducting wire being provided with a direct electric current. For example, a first end of the conducting wire may be electrically connected to the first electrically conducting layer and the other end may be electrically connected to the second electrically conducting layer so that the ends of the ferromagnetic pins represent a north pole and a south pole depending on the direction of the current in the composite board. The magnetic strength of an electromagnet is easily calculated by the skilled person and will typically depend on the number of windings of the conducting wire around the ferromagnetic pin. The ferromagnetic material will be permanently magnetised so that regardless of the presence of a current through the composite board the ferromagnetic pins will provide magnetically attractive, or repulsive, forces, and even when the power to the electrical supply module is off magnetic alignment points will exist. By providing a current through the composite board the magnetic forces will be greatly increased so that a coupling unit can be held strongly in place. Electromagnets thus provide a system where a coupling unit can be coupled in alignment when the power is off, and when the power is switched on the coupling unit is held strongly in place in correct alignment. The composite board may comprise one or more electromagnets. When two or more electromagnets are employed it is preferred that at least two electromagnets are oppositely connected to their respective power supplies, e.g. the electrically conducting layers, so that the south pole of one electromagnet faces the outer surface and the north pole of the other electromagnet faces the outer surface.

In an embodiment, the electrical supply module has a single recess as defined above for a coupling unit. In a preferred embodiment, the electrical supply module comprises a plurality of recesses each having a coupling portion as defined above, for a coupling unit. By providing a constant current or a constant voltage between the first layer and the second layer, a flexible system is obtained where external units can be removed or added freely. For example, an external unit, e.g. an external unit comprising a speaker, a USB hub, a mobile phone, a tablet PC, e.g. an iPad, a power bank, such as for charging a smart phone or another portable electronic device, a transmitter/receiver, such as a Bluetooth, WiFi or an Airplay device, a sensor, such as a sensor for temperature, humidity, wind, light, infrared light, UV light, sound, movement, etc., a camera, a microphone, or a lamp, such as an LED lamp, can be connected and disconnected freely without concern of other external units connected to the electrical supply module. Other appropriate components comprise 3D sensors, such as a LIDAR device or a 3D camera, and positioning devices, e.g. GPS, Glonass, Galileo, or BeiDou satellite navigation devices.

In a specific embodiment the electrical supply system comprises an electrical supply module with two or more recesses with coupling portions as defined above, a coupling unit having an electronic component for data collection, e.g. a sensor, and coupling unit having an electronic component for wireless data transmission, e.g. an antenna. Correspondingly, in a specific embodiment the electrical supply module has a first recess for coupling a coupling unit with an external unit with an electronic component for data collection and a second recess for coupling a coupling unit with an external unit with an electronic component for wireless data transmission. When the electrical supply module comprises two or more recesses, e.g. for coupling a coupling unit with external units with electronic components for data collection and data transmission respectively, or for coupling several coupling units with independent electronic components, the coupling portions and the complementary coupling portions may employ identical coupling principles, in particular, the sets of coupling portions and complementary coupling portions may be identical. Thereby, the user is free to couple the coupling unit with the external unit having the electronic components for data collection and the coupling unit with the external unit having the electronic components for data transmission where desired for optimal flexibility. In another embodiment, the coupling unit with the external unit having the electronic components for data collection and the coupling unit with the external unit having the electronic components for data transmission employ different coupling principles with respect to their complementary coupling portion and the coupling portions of the electrical supply module. Thereby, the electrical supply module may be designed to have an optimal positioning for the external unit for data collection and/or an optimal positioning for the external unit for data transmission.

The electronic component for data collection may be any appropriate sensor as defined above, and the electronic component for wireless data transmission may use any wireless data transmission protocol. When the external unit with the sensor is coupled with the coupling portion of a first recess and the a coupling unit with the external unit for wireless data transmission is coupled with the coupling portion of a second recess, data from the sensor can be transferred via the layers of the electrically conducting material, e.g. using PLC, such as direct current power line PLC, to the external unit for wireless data transmission, and the data can then be transmitted via the wireless data transmission protocol employed to an external location. This provides a flexible system where the external unit for wireless data transmission can be positioned optimally with respect to the wireless recipient of the data, for example taking into consideration elements that may block the wireless data signal, relative to the positioning of the sensor. Furthermore, the electrical supply system allows that the sensor, i.e. in the external unit with the electronic component for data collection, can be easily replaced with another external unit having a different sensor without concern of the wireless data transmission, since this is provided by the external unit with an electronic component for wireless data transmission. In a preferred embodiment, the electrical supply module comprises further recesses for coupling units as defined above and the electrical supply system may correspondingly comprise further external units with electronic components for data collection. For example, the electronic components for data collection may be different sensors for collection of different data types, or identical sensors for collection of the same data types.

In a specific embodiment, the recess of the electrical supply module comprises a coupling portion in the shape of a retaining socket that follows the perimeter of the recess where it is in electrical contact with the first electrically conducting layer so that the retaining socket, or “locking ring”, provides the first electrical contact site. The retaining socket may be made from a metal such as stainless steel, copper or nickel, optionally coated with gold, or aluminium coated with copper or gold. The retaining socket may be in electrical contact with a connector element as defined above. However, it is also contemplated that the retaining socket comprises sections representing the second electrical contact site with appropriate electrical insulation between the first electrical contact site and the second electrical contact site. The retaining socket is typically mounted permanently in the recess. The retaining socket may follow the complete perimeter of the recess, or the retaining socket may be located at sections of the perimeter of the recess, e.g. the retaining socket may have a length in the range of 10% to 100% of the length of the perimeter of the recess. In a particular embodiment, the retaining socket deviates from the plane of the outer surface with less than 500 μm in either direction perpendicular to the plane.

It is preferred that the retaining socket itself has an opening, which may have an area compared to the area of the recess without the retaining socket in the range of 10% to 90%. For example, the recess may be circular, e.g. of a diameter in the range of 10 mm to 50 mm, and the retaining socket may likewise be circular of a diameter to encircle the recess and having an opening with a diameter in the range of 10% to 90% of the diameter of the recess. The retaining socket may have the shape of a ring, although other shapes are also contemplated. In particular, the opening of the retaining socket and the recess may have different shapes.

The thickness of the retaining socket relative to the total thickness of the composite board may be chosen freely, but the thickness is typically in the range of 500 μm to 5 mm, e.g. 1 mm to 2 mm. In a certain embodiment, the retaining socket is mounted in the recess so that there is a free space in the range of 500 μm to 2 mm between the retaining socket and the back layer. Thereby, the retaining socket provides the coupling portion for coupling with the complementary coupling portion via a click-lock interaction. For example, the complementary coupling portion may have barbs for interlocking with the retaining socket. The barbs are preferably made from non-conducting, resilient material, e.g. a plastic or polymer, such as ABS.

A retaining socket preferably comprises one or more magnets, especially permanent magnets, to provide alignment points as defined above. Permanent magnets may be integral with the retaining socket. In an embodiment, the retaining socket has a permanent magnet with either its north pole or its south pole facing the outer surface. In an embodiment, the retaining socket has two or more permanent magnets with the north pole of one magnet and the its south pole of another magnet facing the outer surface.

When a retaining socket is employed, the recess may comprise an electrically insulating material. The electrically insulating material serves to prevent contact between the conductor, e.g. the conductor of the coupling unit, and the front layer, and also stabilises the electrical supply module.

In an embodiment, the power supply is contained in an external unit as otherwise defined above. For example, an external unit may contain the power supply but may not have further electronic components. Thus, coupling of the external unit having the power supply can provide power to the composite board. When the power supply is contained in an external unit the composite board may have a coupling portion exclusively allowing coupling of the external unit having the power supply. This prevents that multiple power supplies are connected to the same electrical supply module. In another embodiment the electrical supply module has two or more recesses with identical coupling portions and the power supply is contained in an external unit. This allows flexibility in the positioning of the power supply and further external units on the electrical supply module. It is preferred that the electrical supply system comprises a single power supply provided in an external unit. In this embodiment it is further preferred that the electrical supply module comprises a plurality of coupling portions employing identical coupling principles to couple a plurality of coupling units likewise having identical complementary coupling portions. The external units in the plurality of coupling units may have the same or different electronic components.

By having an anode layer and a cathode layer of an electrically conducting material and a power supply providing a constant voltage or a constant current between the anode layer and the cathode layer a plurality of electronic components in external units may be connected in parallel. Parallel connection of a plurality of electronic components with a constant current or a constant voltage in the electrical supply system provides a flexible system where additional electronic components can be added to or removed from the system in a simple fashion.

Supplying power via the conducting layers removes the need for separate wiring to each electronic component thus providing a simple system. When the electrically conducting material is a metal, in particular aluminium or copper, the resistance of the electrically conducting material is generally so low that the electrical supply module is not limited with respect to size. In particular, the cross-sectional area of the anode layer and the cathode layer will be much larger than wires typically employed in electric supply systems and thereby the resistance of metallic electrically conducting layers will be correspondingly lower.

In an embodiment the electrical supply module comprises, in addition to the recess with a coupling portion defined above, a LED, e.g. permanently mounted on the composite board or in a recess, e.g. a recess in addition to the recess having the coupling portion, in the composite board, which is electrically connected to the first and the second layer of the electrically conducting material. A LED may be mounted in any kind of appropriate adapter, e.g. the LED may be mounted on a circuit board. For example, the composite board may comprise holes allowing electrical connections to be made to the back layer so that a LED mounted on an adapter can be electrically connected to both the front and the back layer, which supply power to the LED. The electrical supply module may have any number of LEDs, e.g. adapters with LEDs, preferably at least two adapters. It is particularly preferred that the electronic component is a LED or a series of LEDs. When the electric supply module comprises a plurality of LEDs or a plurality of series of LEDs the electric supply module may also be referred to as a lighting fixture. The LED preferably has the form of a surface mounted device (SMD). In a series of LEDs the LEDs are electrically serially connected on the circuit board. The LED may be any LED as desired. For example, the LED may provide light of a specific colour, or the LED may provide white light, e.g. of a colour temperature in the range of 1,500 K to 8,000 K. An adapter with white LEDs will typically provide a luminous intensity in the range of from 50 lumen to 500 lumen, although the lighting fixture is not limited to adapters providing luminous intensities in this range.

In a further embodiment, the external unit comprises a LED.

A LED will have a forward voltage (V_{f}) that is needed to power the LED and turn it on. In the context of the invention the electronic component is considered to have a combined forward voltage (V_{f}) for all components on one circuit board. Each adapter in a lighting fixture of the invention will generally have electronic components of the same nominal forward voltage (V_{f}). The forward voltage (V_{f}) may also be referred to as the threshold voltage.

It is preferred that LEDs are located in series of 2 to 10 LEDs. The LEDs will typically have a power rating in the range of 0.1 W to 1.0 W, e.g. 2 to 6, e.g. 4, LEDs may be serially connected on a circuit board and have a power rating in the range of 0.2 W to 0.4 W. However, the LEDs may also have a power rating higher than 1 W, e.g. in the range of 3 W to 10 W, or even higher than 10 W. A circuit board with one or more LEDs may include a resistor, in particular an adjustable resistor, in series with the LED or series of LEDs on the circuit board.

In a certain embodiment the electrical supply module comprises one or more LEDs, e.g. mounted as described above, and the power supply is capable of providing a first constant voltage equal to or higher than the nominal forward voltage (V_{f}) of the LED or LEDs and a second constant voltage below the nominal forward voltage (V_{f}) of the LED or LEDs. Thereby an electrical supply module is provided, i.e. a “lighting fixture”, which has a zero power setting where no electricity is supplied to the electrical supply module, a first power setting where the electricity, i.e. supplied at or above the V_{f}, is sufficient to power both the external unit and the LEDs of the electrical supply module, and a second power setting, i.e. supplied below the V_{f}, is sufficient to power an external unit coupled via the coupling unit in the recess, but not the LEDs. Thus, the lighting fixture may be switched on to provide light and power to the external unit, or the light may be switched off while power is still supplied to the external unit, or the lighting fixture is switched completely off. Appropriate voltages supplied in the first power setting are standard values in the range of 10 V to 40 V, e.g. 12 V or 24 V, and appropriate voltages supplied in the second power setting are standard values in the range of 1 V to 10 V, e.g. 5-9 V. Appropriate electronic components for the second power setting comprise sensors, e.g. microphones, cameras, temperature sensors, humidity sensors, motion sensors, etc., optionally including a processor to control the power setting of the electrical supply module depending on signals from the sensor. This embodiment is suited for surveillance of a parameter recorded by the sensor and controlling the light from the LEDs in response to a signal from the sensor. This embodiment is also useful as a lamp that can also serve as a charging station of an external device, e.g. a mobile phone, tablet PC, PC, camera, etc.

In a certain embodiment the electrical supply module comprises from 2 to 300 recesses for coupling units. In another embodiment the electrical supply module comprises up to 1000 recesses for coupling units, e.g. 1 to 1000 coupling units, with external units with electronic components. The recesses can be positioned freely on the surface of the composite board, since the layers of conducting material supply power to the electronic components. Especially when the electrically conducting layers are metallic the resistance between recesses, and thereby the coupling units, will be insignificant regardless of the distance between the recesses. Thus, the positioning of the recesses on the composite board is independent of electrical wiring or specific positions on a circuit board. Thus, the coupling units may be positioned freely on the surface defined by the composite board. For example, the recesses may be positioned at regular intervals, e.g. with a distance between the recesses in the range of from 25 mm to 1000 mm, e.g. about 100 mm or 200 mm. An electrical supply module with a large distance, e.g. 500 mm or more, between the recesses can also take advantage of the flexibility described above—in particular the lack of individual wiring is an advantage for electrical supply modules having a distance between the recesses at 500 mm or more. Likewise, the distance between the recesses may also be smaller, e.g. in the range of 100 mm to 300 mm, such as about 200 mm.

The recesses can also be positioned in different patterns in the composite board, since the positioning is independent on any wiring as the electrically conducting layers supply the electronic components with power.

In a certain embodiment, passive units are used to block the recesses in the electrical supply module. A passive unit may be used for coupling with any embodiment of the electrical supply module. The passive unit comprises a complementary coupling portion complementary to the coupling portion of the recess, but it does not comprise any electrical connection points. Thereby, the passive unit prevents undesired contact, e.g. of any electrically conducting material, with the first and the second layer of the electrically conducting material so that short circuits are prevented. Likewise, an end user may be protected from electrical shocks. Furthermore, by blocking the recesses of the electrical supply module with passive units an aesthetically more pleasing electrical supply module is provided.

The composite board may have any shape as desired as long as it comprises the at least two layers, i.e. the anode layer and the cathode layer, of electrically conducting material separated by the electrically insulating material. The anode layer and cathode layer are separated by an insulator of electrically insulating material. In the context of the invention the term “separate” and its derived forms mean that direct electrical contact between the anode layer and the cathode layer is prevented in order to prevent short circuits between the anode layer and the cathode layer. The composite board may comprise additional elements as desired in order to separate the anode layer and the cathode layer, or the insulator of the electrically insulating material may be the only element separating the anode layer and the cathode layer.

The size of the composite board may be selected freely. In general, the composite board has a thickness reflecting the thickness of the insulator, e.g. in the form of an electrically insulating layer, plus the two electrically conducting layers. The thickness of the composite board is typically in the range of 2 mm to 50 mm. The other two dimensions will typically reflect the intended use of electrical supply module and in a certain embodiment the composite board has a size according to recognised standards. For example, the composite board may be sized to fit under e.g. a kitchen cabinet, or other cabinets, or the like. Thus, the electrical supply module may have a width of about 600 mm. The length, e.g. the length for an electrical supply module to fit under a cabinet, may be adjusted by cutting a section off. Removal of a section of the electrical supply module can be done freely, even if the removed section comprises recesses for coupling units.

In another embodiment the electrical supply module is designed to replace a copper wire for supplying electricity to electronic components, and it has a width in the range of 10 to 100 mm, e.g. 30 mm to 50 mm, such as about 40 mm. In this embodiment the electrical supply system may also be referred to as a “rail”; a rail may contain modules, i.e. the electrical supply module and extension modules, of a length in the range of 100 cm to 200 cm.

The composite board may be extending in two dimensions so that it can be described as “planar”. A planar composite board is not limited with respect to thickness, and in general the thickness is defined by the combined thicknesses of the anode layer, the cathode layer and the insulator. The composite board may also be defined in three dimensions and e.g. have a shape representing a section of a sphere, e.g. a hemispherical shape, or an arch. Non-planar composite boards will also have a thickness is defined by the combined thicknesses of the anode layer, the cathode layer and the insulator, and a non-planar composite board is also not limited with respect to its thickness.

The electrically conducting material may be chosen freely, and the conducting layers may be from any conducting material. Likewise, the conducting material may have any thickness as desired. However, it is preferred that the electrically conducting material comprises or is a metal. Preferred metals are metals selected from the list consisting of aluminium, magnesium, copper, titanium, steel, and their alloys. Metals may be anodised to provide the metal with an oxide layer on the surface, and in an embodiment the metal is anodised, e.g. by providing an oxide layer having a thickness of at least 10 μm. When the metal is anodised, the outer surface of the metal is electrically insulating so that an end user is protected from currents running through the electrically conducting materials, i.e. the anode layer and the cathode layer. Anodisation further protects the metal from being corroded. In particular, an electric current running through the anode layer or the cathode layer can make the metal more prone to corrosion but by anodising the metal such corrosion is prevented. Anodisation is especially relevant when the anode layer and/or the cathode layer is constructed from aluminium, magnesium or titanium, or alloys based on these metals. For example, these layers may be anodised to provide oxide layers of at least 10 μm thickness, e.g. about 20 μm Al₂O₃. Anodised aluminium, magnesium, or titanium has a protective insulating layer prevented short circuiting and electrical shocks.

Regardless of any anodisation the surfaces of the composite board, e.g. the surfaces of the electrically conducting layers, may also be provided, e.g. be fully coated, with a layer of paint. The paint may be selected to be electrically insulating.

In further embodiments, the electric supply module comprises additional electrically conducting layers, e.g. between the anode layer and the cathode layer. Additional electrically conducting layers may be used to provide communication to electronic components. When data communication is desired the composite board may be fitted with appropriate data ports, e.g. standardised ports, such as those known as USB, HDMI, Display Port, etc. When data ports are included, appropriate electronic components will typically also be integrated in the composite board. Data ports may be included in the electrical supply module and also in the extension module.

In an embodiment the anode layer and/or the cathode layer is a sheet metal with a thickness up to 5 mm. e.g. in the range of 0.3 mm to 0.7 mm, or in the range of 0.5 mm to 2.0 mm. A preferred metal for the conducting layers is aluminium, e.g. in the form of sheets with a thickness up to 5 mm, e.g. in the range of 0.3 mm to 0.7 mm, or in the range of 0.5 mm to 2.0 mm. Likewise, sheets of copper, magnesium or titanium are also relevant, and the thickness may be up to 5 mm, e.g. in the range of 0.3 mm to 0.7 mm, or in the range of 0.5 mm to 2.0 mm. In a specific embodiment the anode layer and/or the cathode layer is a sheet of copper, optionally coated with an electrically insulating material, e.g. lacquer or paint, on the surface opposite the surface in contact with the insulator.

In an embodiment the anode layer and/or the cathode layer has been extruded from a metal, e.g. from aluminium, magnesium, copper, titanium, or steel. Extrusion allows preparation of an anode layer and/or a cathode layer having a non-uniform thickness. In a preferred embodiment the anode layer and the cathode layer are extruded, e.g. from aluminium or magnesium. In a specific embodiment the anode layer and the cathode layer are rotationally symmetrical with respect to the cross-section of the electrical supply module. It is also possible that the anode layer and/or the cathode layer are manufactured by extrusion of a polymer material, e.g. a thermoplastic polymer, which is subsequently coated with a metallic layer to make the layer electrically conducting. In particular, the metallic coating will be between the extruded polymer and the insulator in order to prevent direct contact of an end user with the electrically conducting layers.

The insulator may have any form desired and the electrically insulating material may be any electrically insulating material. It is preferred that the insulating material comprises a flame retardant. In an embodiment the insulator has the form of a sheet between the anode layer and the cathode layer, which may also be in the form of sheets, or which may be extruded to have another form. When the insulator has the form of a sheet its area generally corresponds to at least 50% of the area of the anode layer and/or the cathode layer. The insulator may also define a honeycomb structure or another discontinuous structure. For example, the insulator may take the form of a plurality of pillars or the like between the anode layer and the cathode layer. A plurality of pillars is especially preferred when the electrically conducting layers have been extruded.

The electrically insulating material is preferably a polymeric material. The electrically insulating material may be of low density. For example, the electrically insulating material may comprise an expanded or foamed material (open and/or closed celled), such as expanded polystyrene, and/or a reinforced material such as a fibre glass material. The electrically insulating layer may be made of a polymer material such as amorphous plastic materials (e.g. polyvinylchloride, polycarbonate and polystyrene) or crystalline plastic materials (e.g. Nylon, polyethylene and polypropylene), or wood. In a certain embodiment the electrically insulating material is polyethylene or the like and has a thickness of at least 0.2 mm, e.g. in the range of 1 mm to 6 mm, e.g. 3 mm or 5 mm. A specific composite board is marketed as a Dibond® plate. When the electrically insulating layer is made from wood it will generally be thicker, e.g. in the range of 10 mm to 20 mm. In a certain embodiment the insulator comprises several different materials. It is significant that the insulator separates the anode layer from the cathode layer in order to prevent short circuits, and it is possible that the insulator comprises an electrically conducting material as long as the anode layer is separated from the cathode layer. For example, the insulator may comprise a core of a different material, even a metal, providing strength and rigidity. In a further embodiment the insulator comprises materials of different thermal expansion coefficients so that assembly of the insulator under increased temperature can provide a material of greater rigidity than expected from the individual materials.

In an embodiment the anode layer and the cathode layer, which may be extruded metals, are glued together with an electrically non-conducting glue so that the glue is the insulator. This allows a thinner layer of the insulator, e.g. in the range of 0.2 mm to 1 mm, since the insulator can be applied in a liquid form, e.g. at ambient temperature, so that the total thickness of the electrical supply module is thinner than can be achieved using a solid material as insulator. It is preferred when the insulator is a glue that the recess for the adapter is made in the anode layer or the cathode layer as desired before gluing the electrically conducting layers together.

It should be understood that combinations of the features in the various embodiments and aspects are also contemplated, and that the various features, details and embodiments may be freely combined into other embodiments. In particular, it is contemplated that all definitions, features, details, and embodiments regarding the electrical supply module, the coupling unit, the external unit and the electrical supply system apply equally to one another.

Reference to the figures serves to explain the invention and should not be construed as limiting the features to the specific embodiments as depicted.

### BRIEF DESCRIPTION OF THE FIGURES

In the following the invention will be explained in greater detail with the aid of an example and with reference to the schematic drawings, in which

FIG. 1 shows an exploded view of an electrical supply module of the invention;

FIG. 2 shows a composite board of an electrical supply module of the invention;

FIG. 3 shows a recess in a composite board of an electrical supply module of the invention;

FIG. 4 shows a perspective top view of a coupling unit of an electrical supply module of the invention;

FIG. 5 shows a perspective top view of an external unit of the invention;

FIG. 6 shows a cross-sectional view of an electrical supply system of the invention;

FIG. 7 shows an exploded view of an electrical supply system of the invention.

Reference to the drawings serves to explain the invention and should not be construed as limiting the features to the specific embodiments as depicted.

### DETAILED DESCRIPTION OF THE INVENTION

The present invention relates to an electrical supply module 1 comprising a composite board 2, and a coupling unit 6 as defined above. The coupling unit 6 can be attached to an external unit 10 having an electronic component 11, which is provided with power from the composite board 2. The electrical supply module 1 may also comprise a power supply 90, e.g. providing a constant voltage of direct current. The invention further relates to an electrical supply system 100 comprising the electrical supply module 1, the coupling unit 6, and the external unit 10 of the invention. The external unit 10 may comprise an electronic component 11, e.g. a component selected from the list consisting of a light emitting diode (LED), a series of LEDs, a resistor, a transistor, a controller, a chip on board (COB), a driver, a speaker, a USB hub, a power bank, a microphone, a camera, a sensor, a 3D sensor, a positioning device, a transmitter, a radio transmitter, a receiver, a radio receiver, an antenna, an access point for wireless communication, and a projector, or an electronic component may be part of the composite board 2. The invention thus provides a greatly flexible system for supplying electricity to the electronic component.

The power supply 90 may use any standardised voltage, e.g. in the range of 5 V to 12 V, although higher voltages, e.g. 24 V, 36 V or 48 V, are also contemplated. It is preferred that the power supply 90 provides a direct current of constant voltage. It is further preferred that the power supply 90 is capable of providing a direct current of constant voltage below a nominal voltage of the electrical supply system 1 and a constant voltage at or above the nominal voltage.

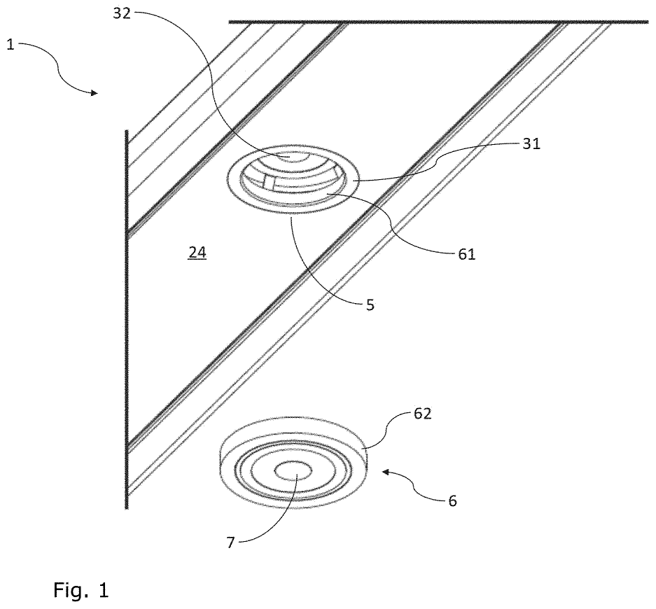

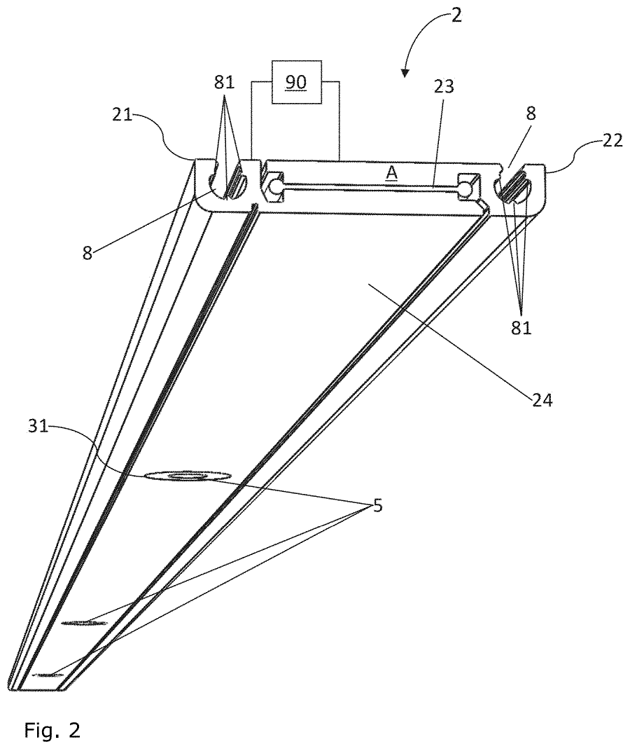

Referring now to the figures, FIG. 1 shows an exploded view of an electrical supply module 1 with the coupling unit 6 seen from below, and the composite board 2, likewise seen from below, is shown in FIG. 2. In an embodiment, the composite board 2 comprises two conductive layers 21, 23 that have been extruded from aluminium, magnesium or titanium; the extruded metals have subsequently been anodised to provide an oxide layer of about 20 μm thickness. The oxide layer provides an electrically insulating layer to the outer surface 24 of the first conducting layer 21.

The first conducting layer 21 is separated from the second conducting layer 22 by an insulator 23 of an electrically insulating material, e.g. polyethylene or polypropylene. The thickness of the insulator 23 is about 1 mm, and the total thickness of the composite board 2 is about 5 mm. In another embodiment, the first conducting layer 21 and the second conducting layer 22 are glued together, and the glue may be the insulator 23. When the insulator 23 is a layer of glue the thickness of the insulator 23, i.e. the glue layer, is typically in the range of 0.2 mm to 0.5 mm.

In the embodiment shown in FIG. 2 the composite board 2 is constructed for coupling with an extension module, in particular an extension module as described in WO 2018/077359. Any embodiment of the extension module, i.e. the composite board 2, disclosed in WO 2018/077359 is contemplated for the present electrical supply module 1, and its contents are hereby incorporated by reference. The composite board 2 has a connection surface A, and the first layer 21 and the second layer 22, e.g. the “anode layer” and “the cathode layer”, respectively, each has a trench 8 extending from the connection surface A. The trenches 8 have ridges 81 defining a circle in the plane of the cross-section of the trenches 8, e.g. in the plane of the connection surface A.

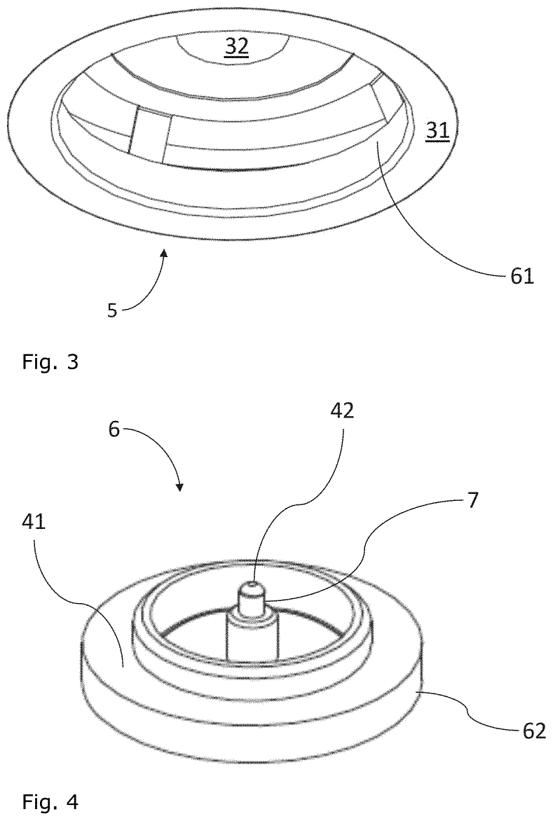

A recess 5, as also illustrated in FIG. 3, is provided in the composite board 2 extending through electrically insulating layer, the outer surface 24, the first layer 21 and the electrically insulating material 23. A locking ring is press-fitted into the recess 5 to provide a first electrical contact site 31 along the recess 5, and the recess 5 provides access to a second electrical contact site 32 at the second layer 22. The locking ring is made from stainless steel and it is in electrical contact with the first layer 21. The locking ring may be permanently magnetic or a permanent magnet may be included in the composite board to provide the coupling portion 61. The recess 5 having a locking ring may also be referred to as a female socket, and it is also contemplated that the locking ring may be the coupling portion 61 of a male-female interaction.

In the embodiment shown, the recess 5 has a circular perimeter, and the coupling unit 6, as shown in FIG. 4, can be mounted in the recess 5. The coupling unit 6 may have a ferromagnetic material or a permanent magnet, preferably a permanent neodymium/iron/boron (NdFeB) magnet, as the complementary coupling portion 62. When both the coupling portion 61 and the complementary the coupling portion 62 comprise a magnet, these will represent alignment points and they will be positioned so that the north pole of the magnet of the coupling portion 61 faces the south pole of the magnet of the complementary coupling portion 62, or vice versa. Alternatively, the coupling unit 6 may be the “male part” of a male-female interaction with the locking ring.

The recess 5 thus has a coupling portion 61 complementary to a complementary coupling portion 62 of the coupling unit 6.

The coupling unit 6 has a conductor 7 in the shape of a pogo-pin, which provides a first electrical contact area 41 and a second electrical contact area 42 for establishing electrical connection between the first electrical contact site 31 and the first electrical contact area 41, and between the second electrical contact site 32 and a second electrical contact area 42, when the coupling unit 6 is coupled with the coupling unit 6 mounted in the recess 5.

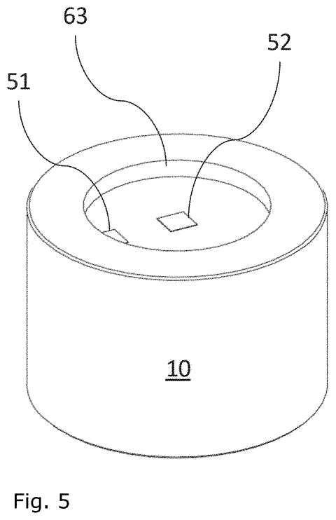

The coupling unit 6 is attached to an external unit 10 (FIG. 5). In the embodiment shown, the external unit 10 has a circular depression with electrical contact points, e.g. a first electrical contact point 51 and a second electrical contact point 52, for establishing contact to the layers 21,22 of the composite board 2 via the first electrical contact area 41 and the second electrical contact area 42 of the coupling unit 6, when the coupling unit 6 is mounted in the recess 5. The circular depression has a perimeter 63 of a size allowing the complementary coupling portion 62 to be press-fitted into the depression. This generally represents a “releasable” attachment of the coupling unit 6 and the external unit 10. However, it is also possible to permanently attach the coupling unit 6 and the external unit 10; for example, the coupling unit 6 and the external unit 10 may be attached by gluing, welding, soldering, etc.

The external unit 10 has an electronic component. In a certain embodiment, the external unit 10 has circuit with a plurality of electronic components. When the external unit 10 has circuit with a plurality of electronic components 11 the circuit with the electronic components is preferably located on a circuit board, e.g. a printed circuit board (PCB).

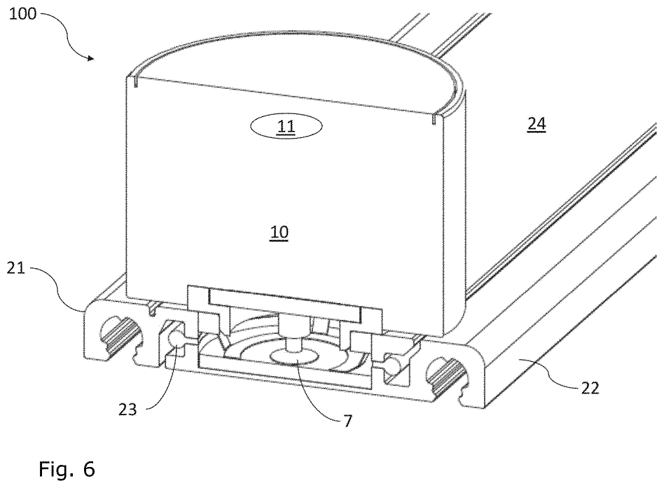

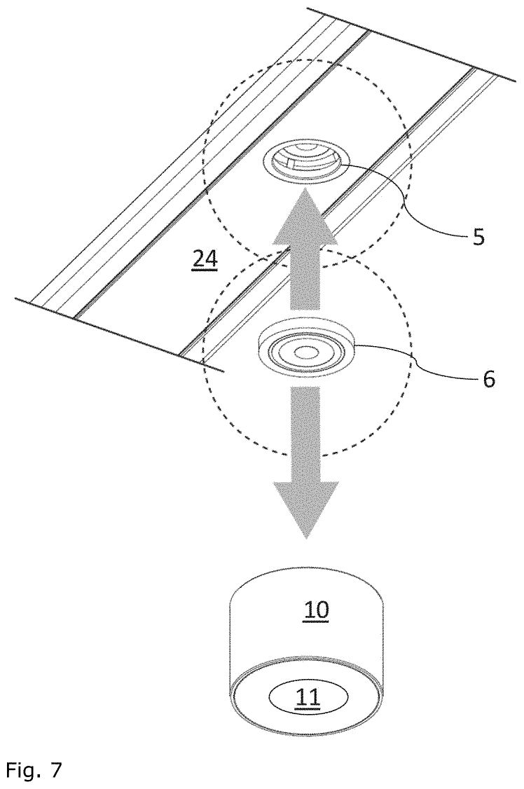

In FIG. 6 a cross-sectional view of an electrical supply system 100 of the invention is shown where the external unit 10 is attached to the coupling unit 6, which is mounted in the recess 5 to ensure releasable coupling between the coupling portion 61 and the complementary coupling portion 62. Both the attachment and the coupling between the respective parts will be strong enough, e.g. due to the magnetic forces, so that the external unit 10 can be held strongly in place and the electrical supply system 100 can be oriented freely without risk of uncoupling the coupling unit 6 and the external unit 10, e.g. due to gravity.

FIG. 7 shows an exploded view of the electrical supply system 100 of the invention where the arrows indicate how the coupling unit 6 may be attached to the external unit 10 before mounting the coupling unit 6 in the recess 5 or how the coupling unit 6 may be mounted in the recess 5 before attaching to the external unit 10 with the coupling unit 6 when this is mounted in the recess 5.

1. An electrical supply module comprising:
a composite board comprising a first layer and a second layer of an electrically conducting material, which first layer and second layer are separated by an insulator of an electrically insulating material, which first layer forms an outer surface comprising a first electrical contact site, the composite board having a recess extending through the outer surface, the first layer and the electrically insulating material, which recess allows access to a second electrical contact site at the second layer, the recess having a coupling portion, and
a coupling unit for attaching to an external unit using direct current, the coupling unit having a complementary coupling portion allowing releasable coupling with the coupling portion of the recess, a first electrical contact area and a second electrical contact area,
wherein coupling of the coupling portion and the complementary coupling portion establishes electrical connection from the first electrical contact site to the first electrical contact area and electrical connection from the second electrical contact site to the second electrical contact area, whereby the attachment of the external unit to the coupling unit allows for the correct current direction to the external unit.

2. The electrical supply module according to claim 1, wherein the electrical supply module comprises a plurality of recesses and a plurality of coupling units.

3. The electrical supply module according to claim 1, wherein the coupling portion and/or the complementary coupling portion comprise(s) one or more magnets.

4. The electrical supply module according to claim 1, wherein the coupling unit and/or the recess comprise(s) a conductor for establishing electrical connection from the second electrical contact site to the second electrical contact area of the coupling unit when the coupling unit is coupled in the recess.

5. The electrical supply module according to claim 4, wherein the conductor comprises electrical insulation adapted to prevent contact between the conductor and the electrically conducting first layer.

6. The electrical supply module according to claim 1, wherein the outer surface comprises an electrically insulating layer, and a hole through the electrically insulating layer of the outer surface allows electrical contact to the first electrical contact site.

7. The electrical supply module according to claim 1, wherein the electrical supply module has a nominal voltage and the electrical supply module further comprises a power supply capable of providing between the first layer and the second layer, a first constant voltage equal to or higher than the nominal voltage and a second constant voltage lower than the nominal voltage.

8. The electrical supply module according to claim 7, wherein the composite board has an electronic component having the nominal voltage, or wherein the external unit has an electronic component having the nominal voltage.

9. The electrical supply module according to claim 7, wherein the electrical supply module comprises a light emitting diode (LED) electrically connected to the first layer and the second layer of electrically conducting material, and the power supply is capable of providing a first constant voltage equal to or higher than a nominal forward voltage (V_{f}) of the LED and a second constant voltage below the nominal forward voltage (V_{f}) of the LED.

10. A coupling unit for coupling in a recess of an electrical supply module comprising a composite board comprising a first layer and a second layer of an electrically conducting material, which first layer and second layer are separated by an insulator of an electrically insulating material, which first layer forms an outer surface comprising a first electrical contact site, the composite board having a recess extending through the outer surface, the first layer and the electrically insulating material, which recess allows access to a second electrical contact site at the second layer, the recess having a coupling portion;
the coupling unit comprising a complementary coupling portion complementary to the coupling portion of the recess of the electrical supply module, a first electrical contact area and a second electrical contact area,
wherein coupling of the complementary coupling portion and the coupling portion of the electrical supply module establishes electrical connection from the first electrical contact site of the electrical supply module to the first electrical contact area and electrical connection from the second electrical contact site of the electrical supply module to the second electrical contact area.

11. The coupling unit according to claim 10, which coupling unit is attached to an external unit having an electronic component in electrical communication with the first electrical contact area and the second electrical contact area.

12. The coupling unit according to claim 10 further comprising a conductor for establishing electrical connection from the second electrical contact area to the second electrical contact site of the electrical supply module when the coupling unit is coupled in the recess of the electrical supply module.

13. The coupling unit according to claim 12, wherein the conductor comprises a spring.

14. The coupling unit according to claim 11, wherein the electronic component is selected from the list consisting of a light emitting diode (LED), a series of LEDs, a resistor, a transistor, a controller, a chip on board (COB), a driver, a speaker, a USB hub, a power bank, a microphone, a camera, a sensor, a 3D sensor, a positioning device, a transmitter, a radio transmitter, a receiver, a radio receiver, an antenna, an access point for wireless communication, and a projector.

15. An electrical supply system comprising an electrical supply module according to claim 1, and an external unit having an electronic component, which external unit is adapted to being attached to the coupling unit so that an electrical circuit between the electronic component, the first electrical contact area and the second electrical contact area is established when the external unit is attached to the coupling unit.

16. The electrical supply system according to claim 15, wherein the electrical supply module comprises a plurality of recesses and a plurality of coupling units, wherein electrical supply system comprises:
a first coupling unit attached to the external unit having a first electronic component in electrical communication with the first electrical contact area and the second electrical contact area, wherein the first electronic component is selected from the list consisting of a light emitting diode (LED), a series of LEDs, a resistor, a transistor, a controller, a chip on board (COB), a driver, a speaker, a USB hub, a power bank, a microphone, a camera, a sensor, a 3D sensor, a positioning device, a transmitter, a radio transmitter, a receiver, a radio receiver, an antenna, an access point for wireless communication, and a projector, wherein the first electronic component is for data collection; and
a further coupling unit attached to the external unit having a further electronic component in electrical communication with the first electrical contact area and the second electrical contact area, wherein the further electronic component is selected from the list consisting of a light emitting diode (LED), a series of LEDs, a resistor, a transistor, a controller, a chip on board (COB), a driver, a speaker, a USB hub, a power bank, a microphone, a camera, a sensor, a 3D sensor, a positioning device, a transmitter, a radio transmitter, a receiver, a radio receiver, an antenna, an access point for wireless communication, and a projector,
wherein the external unit is an electronic component for wireless data transmission.
